(19) United States
(12) Patent Application Publication
(10) Pub. No.: US 2006/0043536 A1
(43) Pub. Date: Mar. 2, 2006

(54) Implanted photoresist to reduce etch erosion during the formation of a semiconductor device

(76) Inventors: Chih-Chen Co, Hsinchu (TW); Daniel A. Steckert, Boise, ID (US)

Correspondence Address: Kevin D. Martin;Micron Technology, Inc., 8000 S Federal Way, MS 1-525, Boise, ID, 83716, US

(21) Appl. No.: 10/931,655

(22) Filed: Aug. 31, 2004

(51) Int. Cl. H01L 23/58; H01L 21/461

(52) U.S. Cl. 257/632; 438/725; 438/780

(57) ABSTRACT

A method for forming a semiconductor device comprises forming a layer to be etched, and forming a patterned photoresist layer over the layer to be etched. The patterned photoresist layer is treated prior to etching, for example by implantation with argon or nitrogen. This treatment reduces the volume of the photoresist, possibly by densifying the layer, which results in the photoresist layer being more resistant to an etch and decreasing the size of the feature to be formed. After treating the photoresist layer, the layer to be etched is exposed to an etchant.

### FIELD OF THE INVENTION

This invention relates to the field of semiconductor manufacture and, more particularly, to a method for decreasing the size of a feature which may be formed using conventional lithography.

### BACKGROUND OF THE INVENTION

During the manufacture of a semiconductor device, many different device features are formed using lithography methods such as optical lithography. FIGS. 1-4 depict an exemplary method for forming a transistor gate using conventional technology. FIG. 1 depicts an in-process semiconductor wafer assembly comprising a semiconductor wafer 10 having the following blanket layers formed thereover: a gate oxide layer 12; a polysilicon layer 14 formed over the gate oxide layer 12; a silicide layer 16 such as tungsten silicide which enhances conductivity of the completed transistor gate; and a dielectric layer 18 such as silicon nitride capping layer. FIG. 1 further depicts a patterned photoresist (resist) layer 20 which is used to define the transistor gate stack. A photoresist layer between about 3,200 angstroms (Å) and about 3,600 Å thick is typically used with current conventional transistor formation. The pitch of the photoresist is between about 2,200 Å and about 2,400 Å, with spacing between adjacent photoresist portions of between about 1,100 Å and about 1,200 Å. It should be noted that the structure of FIG. 1 may have various other elements which are not immediately germane to the present invention, such as shallow trench isolation (STI or “field oxide”), doped wafer regions such as wells or source/drain regions. Further, the transistors depicted in the FIGS. may have a different spacing scheme.

As is well known in the art, the photoresist 20 is initially formed as a blanket layer which is exposed to a light pattern which alters the chemistry of the exposed photoresist and allows the unexposed portion of the photoresist, in the case of a positive photoresist, to be removed while the exposed portion remains. With a negative photoresist, the unexposed portion remains while the exposed portion is removed. For ease of explanation the remainder of this document describes the use of a positive photoresist, while it is to be understood that the present invention can be easily adapted for a process using a negative photoresist.

An etch is performed on the FIG. 1 structure which removes exposed portions of the dielectric layer 18, the silicide layer 16, the polysilicon layer 14, and stops at (i.e. on or within) gate oxide layer 12 to result in the structure of FIG. 2. During this etch the photoresist erodes and becomes thinner. After forming the FIG. 2 structure the photoresist is removed and a blanket dielectric layer 30 such as silicon nitride is formed to result in the structure of FIG. 3. The blanket silicon nitride layer 30 and the gate oxide layer 16 are etched using a vertically-oriented anisotropic spacer etch to expose the wafer 10 and to result in the structure of FIG. 4 comprising spacers 40. Wafer processing continues according to means known in the art.

It should be noted that there are many variations to transistor formation not related to the use of the present invention. For example, in an alternate process the stack of FIG. 1 is etched down only to the polysilicon 14, the photoresist 20 is removed, a first spacer is formed over sidewalls defined by the capping layer 18 and the silicide 16, then the polysilicon 14 is etched down to the gate oxide and a second spacer is formed over the first spacer and over sidewalls defined by the polysilicon 16.

To form as many transistors as possible, the photoresist layer which defines the transistor gate stack is formed very narrowly, typically as narrowly as allowed by the photolithographic process. Additionally, adjacent transistor gate stacks are formed with minimum spacing, which is typically about the same as the width of the transistor stacks themselves. However, as depicted in FIG. 5, forming features with excessively close spacing, in the exemplary transistor formation process, can result in the spacer layer 50 impinging on itself between the transistor stacks thereby making it difficult or impossible to expose the wafer 10 without reworking the wafer.

One process used to increase the spacing between the photoresist (and therefore between the transistor gate stacks) is referred to as “photoresist trim etch” depicted in FIGS. 6-8. In this process, the structure of FIG. 6 is formed using a method similar to the structure of FIG. 1, except that the photoresist 60 must be formed thicker than that of FIG. 1 for reasons discussed below. With this exemplary use, the photoresist is between about 3,600 Å and about 4,000 Å thick at the step depicted in FIG. 6, with the pitch remaining at between about 2,200 Å and about 2,400 Å and the spacing between adjacent photoresist at between about 1,100 Å and about 1,200 Å. After forming the structure of FIG. 6, the photoresist 60 is exposed to an isotropic plasma etch to remove a portion of all exposed surfaces of the photoresist. The photoresist trim etch may comprise a plasma etch using HBr gas at a flow rate of between about 60 sccm and 100 sccm, Ar gas at a flow rate of between about 40 sccm and 80 sccm, and O₂ gas at a flow rate of between about 2 standard cm³/min (sccm) and about 10 sccm at a chamber pressure of between about 4 millitorr (mT) and 15 mT, a source power of between about 200 Watt and 400 Watt, and a bias power of between about 40 Watt and 80 Watt. This trim etch results in the structure of FIG. 7 in which the vertical and horizontal dimensions of the photoresist have been decreased. For example, the thickness of the photoresist is reduced by about 400 Å, to between 3,200 Å and 3,600 Å. The spacing between the photoresist is increased by about 300 Å, to between 1,400 Å to 1,500 Å.

Subsequent to etching the photoresist to result in the structure of FIG. 7, the transistor gate stack is etched and the spacer layer 30 is formed to result in the structure of FIG. 8, which depicts a narrower transistor gate stack with more space between adjacent transistors than depicted in the FIG. 3 structure. This decreases the possibility of bridging the spacer dielectric 50 as depicted in FIG. 5.

As mentioned above, the photoresist 60 of the trim etch process must be formed thicker than the photoresist 20 of the process of FIGS. 1-4 to survive the etch of the transistor gate stack, because its thickness is reduced during the trim. If the photoresist is not formed thicker with the trim etch process it may be completely removed during the etch. Exposing the capping layer 18 results in its thinning, and reduced protection of the conductive portions 16, 18 of the completed transistor. A disadvantage of increasing the thickness of the photoresist is that as the thickness of the photoresist increases it becomes more difficult to properly expose the photoresist during patterning, and the lithography resolution may be decreased with increasing photoresist thickness.

A method for forming semiconductor features having a reduced size without increasing the thickness of the photoresist as is required with a photoresist trim etch would be desirable.

### SUMMARY OF THE INVENTION

The present invention provides a new method which, among other advantages, allows for the forming a semiconductor device feature having smaller dimensions than those defined by a prior optical lithography process. The smaller dimensions can be formed without requiring an etch of the photoresist. Further, the photoresist layer formed with an embodiment of the present process may be thinner than with prior processes because it becomes more resistant to a subsequent etch. This results from a process which dopes the photoresist layer and which densifies, shrinks, and hardens the patterned photoresist layer and allows for improved lithography resolution.

Additional advantages will become apparent to those skilled in the art from the following detailed description read in conjunction with the appended claims and the drawings attached hereto.

### BRIEF DESCRIPTION OF THE DRAWINGS

FIGS. 1-4 are cross sections depicting steps of a first conventional process for forming a plurality of transistors;

FIG. 5 is a cross section depicting a problem which may be encountered with inadequate spacing between semiconductor device features during conventional formation;

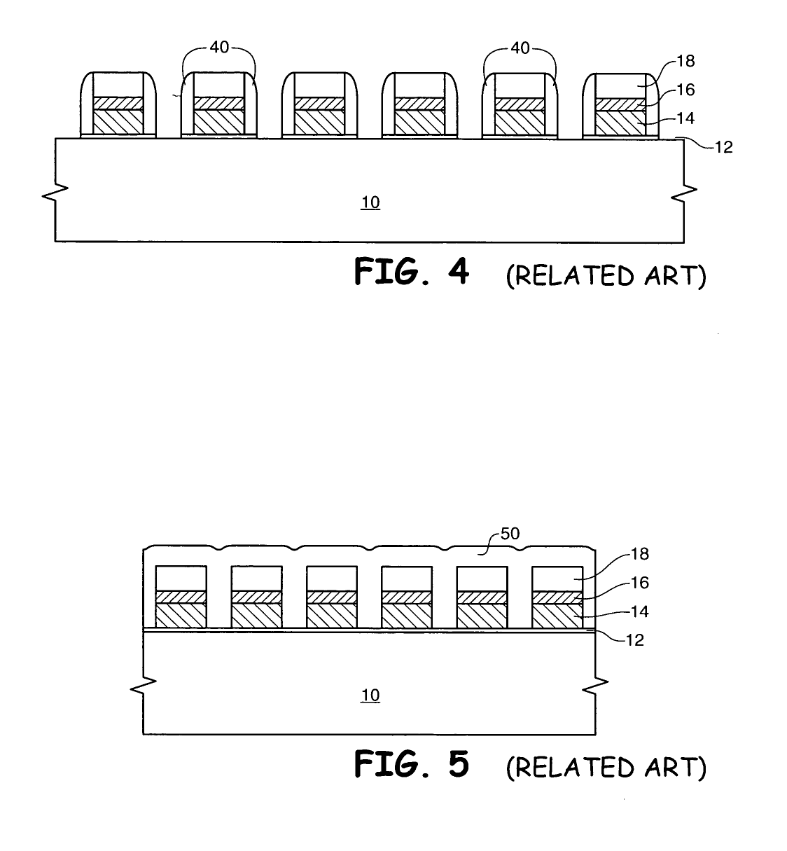

FIGS. 6-8 are cross sections depicting steps of a second conventional process for forming a plurality of transistors;

FIGS. 9-11 are cross sections depicting an embodiment of an inventive method for forming a plurality of transistors;

FIG. 12 is an isometric depiction of various components which may be manufactured using devices formed using an embodiment of the present invention; and

FIG. 13 is a block diagram of an exemplary use of the invention to form part of a transistor array in a memory device.

It should be emphasized that the drawings herein may not be to exact scale and are schematic representations. Unless noted, the drawings are not intended to portray the specific parameters, materials, particular uses, or the structural details of the invention which can be determined by one of skill in the art by examination of the information herein.

### DETAILED DESCRIPTION OF THE PREFERRED EMBODIMENT

The term “wafer” is to be understood as a semiconductor-based material including silicon, silicon-on-insulator (SOI) or silicon-on-sapphire (SOS) technology, doped and undoped semiconductors, epitaxial layers of silicon supported by a base semiconductor foundation, and other semiconductor structures. Furthermore, when reference is made to a “wafer” in the following description, previous process steps may have been utilized to form regions or junctions in or over the base semiconductor structure or foundation. Additionally, when reference is made to a “substrate assembly” in the following description, the substrate assembly may include a wafer with layers including dielectrics and conductors, and features such as transistors, formed thereover, depending on the particular stage of processing. In addition, the semiconductor need not be silicon-based, but could be based on silicon-germanium, silicon-on-insulator, silicon-on-sapphire, germanium, or gallium arsenide, among others. Further, in the discussion and claims herein, the term “on” used with respect to two layers, one “on” the other, means at least some contact between the layers, while “over” means the layers are in close proximity, but possibly with one or more additional intervening layers such that contact is possible but not required. Neither “on” nor “over” implies any directionality as used herein.

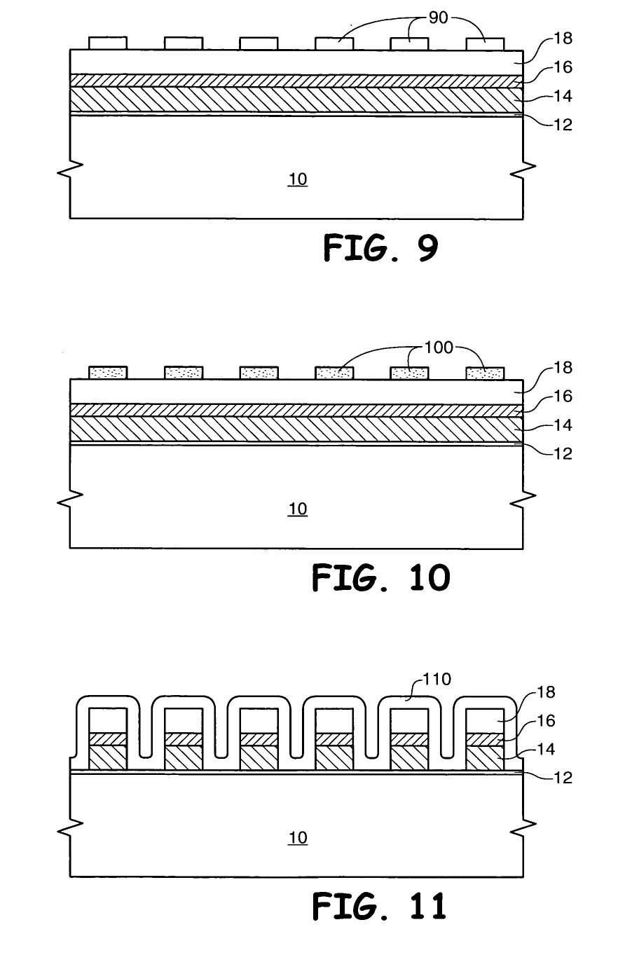

A first embodiment of an inventive method for forming a plurality of semiconductor device features is depicted by FIGS. 9-11. FIG. 9 depicts a semiconductor wafer 10 with the following blanket layers formed thereover: a gate dielectric layer 12, for example a gate oxide layer formed from silicon dioxide; a first conductive layer 14, for example comprising polysilicon; a conductive enhancement layer 16 such as tungsten silicide; and a protective dielectric layer 18 for example comprising a silicon nitride capping layer. These layers can be easily formed by one of ordinary skill in the art from the description herein. While the thickness of each of these layers depends on a number of different factors including the type of cell and the desired electrical properties of the completed cell, a typical arrangement with current dynamic random access memory technology includes a gate oxide layer having a thickness of between about 30 angstroms (Å) and about 60 Å thick, a polysilicon layer between about 500 Å and about 700 Å thick, a tungsten layer between about 200 Å and about 350 Å thick, and a silicon nitride capping layer between about 1,200 Å and about 1,500 Å thick.

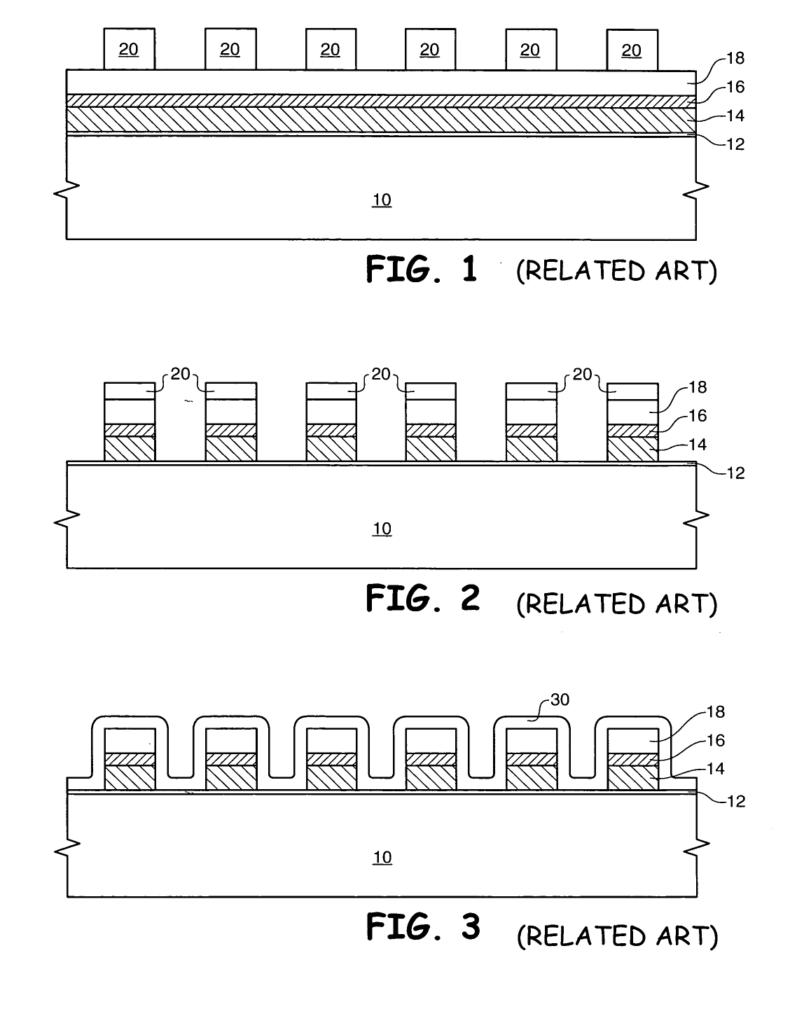

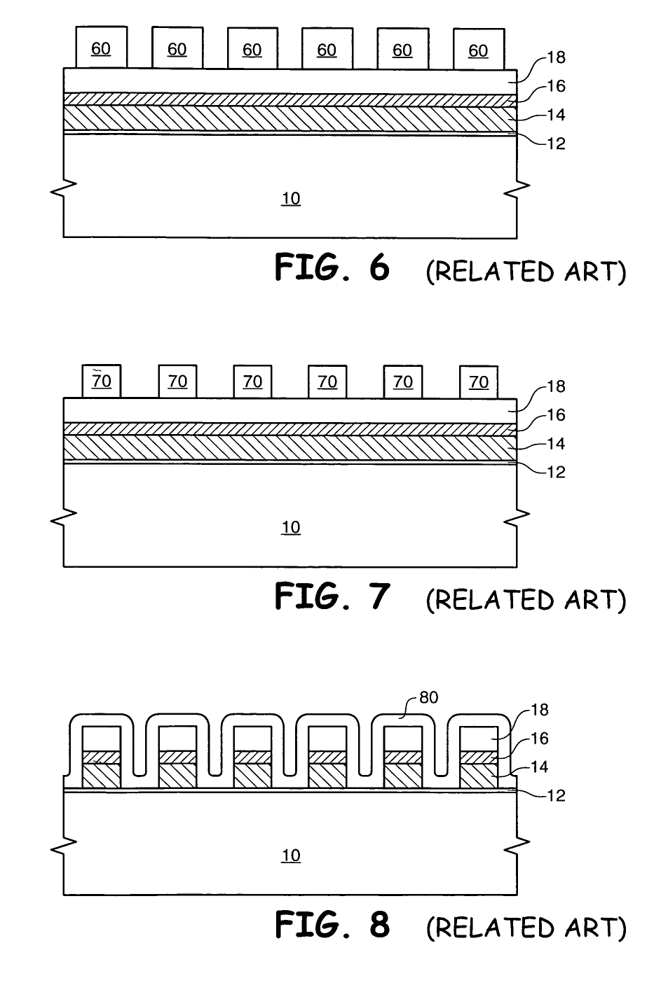

Next, a patterned photoresist layer 90 is formed over the surface of the capping layer 18. The photoresist layer may be formed to have a thinner profile than either the photoresist layer 60 of FIG. 6 or the photoresist layer 20 of FIG. 1, for example between about 2,500 Å and about 3,000 Å thick. This is in contrast to photoresist layer 20 of FIG. 1 which is between about 3,200 Å and about 3,600 Å thick, and the photoresist layer of FIG. 6 which is between about 3,600 Å and about 4,000 Å thick. In this embodiment of the invention, the photoresist layer pattern has a pitch of between about 2,200 A and about 2,400 Å, and the individual portions of the photoresist are spaced from adjacent portions by between about 1,100 Å and about 1,200 Å.

After forming the FIG. 9 structure, the photoresist is implanted with a dopant, for example argon or nitrogen (N₂) to densify, shrink, and harden the photoresist. The mechanism for the densification has not been studied, but it is likely that the implanted ions break chemical bonds within the organic material, causing collapse of local areas. The dopant remains within the photoresist and does not etch the photoresist, yet the volume of the photoresist decreases by about 20% as described below.

The photoresist is doped with the selected material using an ion implant. The dopant is implanted with sufficient energy to drive the dopant an average of between about 45% and about 55% of the way into the photoresist layer, with a target depth of 50% of the way into the photoresist layer. Thus the highest concentration of ions will be about half way through the thickness of the photoresist. The implant energy will depend on the thickness of the photoresist and the dopant used. Chuck temperature is maintained at about 100° C. or less, with ambient being a minimum. The photoresist should be dosed to a concentration of about 1E16 atoms/cm³ with the highest concentration being targeted at about the middle of the thickness of the photoresist. The photoresist layer does not begin to densify until the concentration of dopants is at least about 5E15 atoms/cm³.

The densification results in a volumetric decrease of the photoresist layer of between about 15% and about 25%, for example about 20% (i.e. a reduction to between about 75% and 85% of its original thickness). Thus for photoresist layer 90 described with reference to FIG. 9, the photoresist becomes between about 1,875 Å and about 2,550 Å thick, with an average of between about 2,000 Å and about 2,400 Å. In addition to shrinking the photoresist, the implant results in the photoresist becoming more etch resistant, possibly due to its densification which results in a harder layer. Further, the photoresist layer 100 can be thinner than possible with previous photoresist layers, with the actual thickness depending on the type and duration of the etch which erodes the photoresist. This is an advantage because a thinner photoresist improves the lithographic resolution and allows for the formation of an even smaller feature.

After densification of the photoresist to form the FIG. 10 structure, an etch defines the transistor stack (or other feature being formed) using the patterned, densified photoresist as a pattern. The remaining photoresist is then removed, for example using a conventional ash process in an oxygen plasma followed by a wet clean, then the spacer layer 110 is formed to result in the structure of FIG. 11. Wafer processing then continues according to means known in the art, including a vertically-oriented anisotropic spacer etch.

Implanting photoresist with boron is known to increase the difficulty of removing the photoresist. However, implanting the photoresist with either argon or nitrogen does not make the photoresist more difficult to remove. Further, hardening and densifying the photoresist results in the photoresist being more resistant to the etch being performed on the underlying layer, which may result in the underlying layer having an improved edge subsequent to the etching. This results from the photoresist maintaining its shape while the etching is being performed.

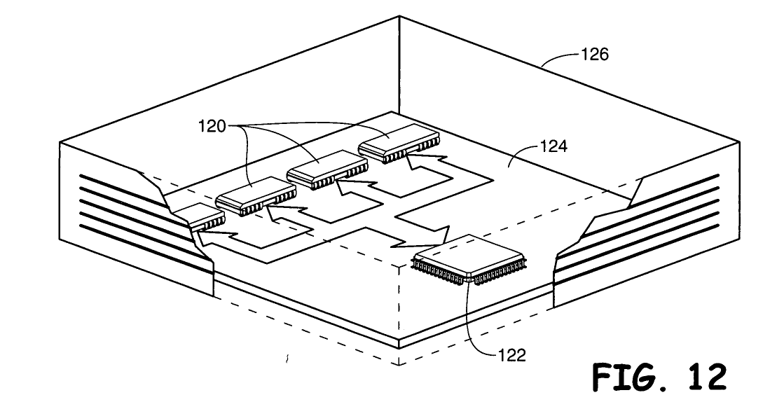

As depicted in FIG. 12, a semiconductor device 120 formed in accordance with the invention may be attached along with other devices such as a microprocessor 122 to a printed circuit board 124, for example to a computer motherboard or as a part of a memory module used in a personal computer, a minicomputer, or a mainframe 126. FIG. 12 may also represent use of device 120 in other electronic devices comprising a housing 126, for example devices comprising a microprocessor 122, related to telecommunications, the automobile industry, semiconductor test and manufacturing equipment, consumer electronics, or virtually any piece of consumer or industrial electronic equipment.

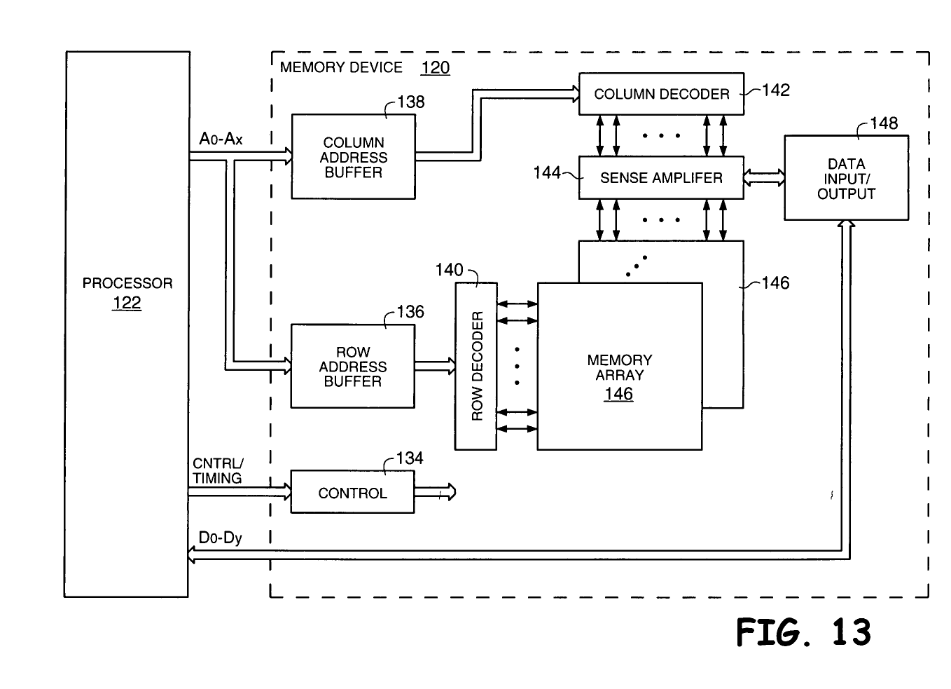

The process and structure described herein can be used to manufacture a number of different structures which comprise a structure formed using a photolithographic process. FIG. 21, for example, is a simplified block diagram of a memory device such as a dynamic random access memory having digit lines and other features which may be formed using an embodiment of the present invention. The general operation of such a device is known to one skilled in the art. FIG. 13 depicts a processor 122 coupled to a memory device 120, and further depicts the following basic sections of a memory integrated circuit: control circuitry 134; row 136 and column 138 address buffers; row 140 and column 142 decoders; sense amplifiers 144; memory array 146; and data input/output 148.

While this invention has been described with reference to illustrative embodiments, this description is not meant to be construed in a limiting sense. Various modifications of the illustrative embodiments, as well as additional embodiments of the invention, will be apparent to persons skilled in the art upon reference to this description. It is therefore contemplated that the appended claims will cover any such modifications or embodiments as fall within the true scope of the invention.

What is claimed is:

1. A method used to form a semiconductor device, comprising:
forming at least one layer to be etched;
forming a patterned photoresist layer over the layer to be etched, the patterned photoresist layer having a first resistance to an etch;
treating the patterned photoresist layer such that subsequent to the treatment the photoresist layer has a second resistance to an etch which is greater than the first resistance to an etch; and
subsequent to treating the patterned photoresist layer, etching the layer to be etched using the treated patterned photoresist layer as a pattern.

2. The method of claim 1 further comprising implanting the patterned photoresist layer during the treating of the patterned photoresist layer.

3. The method of claim 1 further comprising implanting the patterned photoresist layer with argon during the treating of the patterned photoresist layer.

4. The method of claim 1 further comprising implanting the patterned photoresist layer with nitrogen during the treating of the patterned photoresist layer.

5. The method of claim 1 further comprising densifying the patterned photoresist layer during the treating of the patterned photoresist layer.

6. The method of claim 5 wherein the patterned photoresist layer decreases in volume by about 20% during the treating of the patterned photoresist layer.

7. A method for etching a layer during the formation of a semiconductor device, comprising:
forming a layer to be etched over a semiconductor wafer;
forming a photoresist layer over the layer to be etched;
patterning the photoresist layer;
implanting a dopant into the photoresist layer to densify the photoresist layer; and
subsequent to implanting the dopant into the photoresist layer, etching the layer to be etched using the densified patterned photoresist layer as a pattern.

8. The method of claim 7 further comprising implanting the dopant into the photoresist layer to a target depth of half way through a thickness of the photoresist layer.

9. The method of claim 8 further comprising implanting the dopant into the photoresist layer at a target doping concentration of about 1E16 atoms/cm³

10. The method of claim 7 further comprising implanting argon into the photoresist layer during the implanting of the dopant.

11. The method of claim 10 further comprising implanting nitrogen into the photoresist layer during the implanting of the dopant.

12. The method of claim 7 wherein the implanting of the dopant into the photoresist layer results in a volumetric decrease of the photoresist layer of between about 15% and about 25%.

13. A method for treating a photoresist layer, comprising:
forming a photoresist layer over a layer to be etched;
patterning the photoresist layer; and
implanting the photoresist layer with a material selected from the group consisting of nitrogen and argon,
wherein implanting the photoresist layer results in a volumetric decrease of the photoresist layer by between about 15% and about 25%.

14. The method of claim 13 further comprising:
forming the photoresist layer to have a thickness; and
implanting the photoresist layer to a target depth of about 50% of the way through the thickness.

15. The method of claim 13 further comprising implanting the photoresist to a target dopant concentration of about 1E16 atoms/cm³ at the depth of about 50% of the way through the thickness.

16. An in-process semiconductor device, comprising:
a semiconductor wafer substrate assembly comprising at least one layer to be etched, wherein the layer to be etched comprises a first portion to be etched and a second portion to remain unetched;
a densified photoresist layer overlying the second portion of the layer to be etched,
wherein the first portion of the layer to be etched is uncovered by the densified photoresist layer.

17. The in-process semiconductor device of claim 16 further comprising the densified photoresist layer having a dopant concentration of at least about 5E15 atoms/cm³.

18. The in-process semiconductor device of claim 16 further comprising the densified photoresist layer having a dopant concentration of about 1E16 atoms/cm³.

19. The in-process semiconductor device of claim 17 further comprising the densified photoresist layer having a dopant concentration of nitrogen.

20. The in-process semiconductor device of claim 17 further comprising the densified photoresist layer having a dopant concentration of argon.

21. A method used during the formation of a semiconductor device comprising:
forming a photoresist layer over a semiconductor wafer substrate assembly, wherein the photoresist layer has a first resistance to an etch; and
doping the photoresist layer such that subsequent to the doping the photoresist layer has a second resistance to an etch which is greater than the first resistance to the etch.

22. The method of claim 21 wherein the semiconductor wafer substrate assembly comprises a layer to be etched and the method further comprises:
patterning the photoresist layer; and
subsequent to doping the photoresist layer, etching the layer to be etched using the photoresist layer as a pattern.

23. The method of claim 22 further comprising implanting the photoresist layer with a material selected from the group consisting of nitrogen and argon during the doping of the photoresist layer.
